(19) United States
(12) Patent Application Publication
(10) Pub. No.: US 2017/0018726 A1
(43) Pub. Date: Jan. 19, 2017

(54) ELECTRONIC DEVICE AND MANUFACTURING METHOD THEREOF

(71) Applicant: SONY CORPORATION, TOKYO (JP)

(72) Inventor: MAO KATSUHARA, KANAGAWA (JP)

(21) Appl. No.: 15/123,830

(22) PCT Filed: Feb. 5, 2015
(86) PCT No.: PCT/JP2015/053207

§ 371 Date: Sep. 6, 2016

(30) Foreign Application Priority Data
Mar. 14, 2014 (JP) 2014-051079

(51) Int. Cl. H01L 51/05; H01L 51/00

(52) U.S. Cl. CPC H01L 51/052; H01L 51/0545; H01L 51/0541; H01L 51/0017

(57) ABSTRACT

A electronic device includes: a control electrode 11 formed on a base substrate 10; an insulation layer 21 adapted to cover the control electrode 11 and formed of an organic insulation material; an active layer 12 formed on the insulation layer 21, formed of an organic semiconductor material, and subjected to patterning; and a first electrode 13A and a second electrode 13B formed on the active layer 12, in which a chemical composition of a surface of a region A (21A) that is a region of the insulation layer 21 not formed with the active layer 12 differs from a chemical composition of a region B (21B) that is a region of the insulation layer 21 located under the active layer 12.

### TECHNICAL FIELD

The present disclosure relates to an electronic device and a manufacturing method thereof.

### BACKGROUND ART

In the case of manufacturing an electronic device such as an organic thin film transistor, a structure combined with an organic insulation film formed of an organic insulation material is often adopted in order to take advantage of flexibility of the organic thin film transistor. Since the organic insulation material has an insulation property equivalent to an inorganic insulation material and also is the material having flexibility, the organic insulation material is an indispensable material in order to provide flexibility to the electronic device (e.g., Non-Patent Document: Advanded Materials vol. 2, p. 592 (1990), F. Garnier et al.).

### CITATION LIST

### Non-Patent Document

Non-patent Document 1: Advanded Materials vol. 2, p. 592 (1990), F. Garnier et al.

### SUMMARY OF THE INVENTION

### Problems to be Solved by the Invention

On the other hand, in order to manufacture an electronic device as a single element, patterning an organic semiconductor material layer formed of an organic semiconductor material is necessary. The organic semiconductor material layer is patterned on the basis of dry etching normally using oxygen gas. However, normally, etching selectivity can be hardly secured between an organic semiconductor material constituting the organic semiconductor material layer and an organic insulation material constituting an organic insulation film. As a result, the organic insulation film may also be etched at the time of patterning the organic semiconductor material layer. Furthermore, when this kind of phenomenon occurs, a level difference is generated or a level difference at a level difference portion is increased, thereby causing various kinds of problems in subsequent manufacturing steps of the electronic device, such as line disconnection, ununiformity within a surface, insufficient coverage, and ununiform film thickness. Also, degradation of reliability of the electronic device, occurrence of failure, limitation of layout in the electronic device, and the like may be caused.

Therefore, the present disclosure is directed to providing an electronic device having a structure and a composition capable of securing etching selectivity between an organic semiconductor material constituting an organic semiconductor material layer and an organic insulation material constituting an insulation layer at the timing of patterning an organic semiconductor material layer, and a manufacturing method of such an electronic device.

### Solutions to Problems

In order to achieve the above object, an electronic device according to a first aspect of the present disclosure includes:

a control electrode formed on a base substrate;

an insulation layer adapted to cover the control electrode and formed of an organic insulation material;

an active layer formed on the insulation layer, formed of an organic semiconductor material, and subjected to patterning; and

a first electrode and a second electrode formed on the active layer,

wherein a chemical composition of a surface of a region A that is a region of the insulation layer not formed with the active layer differs from a chemical composition of a region B that is a region of the insulation layer located under the active layer.

In order to achieve the above object, an electronic device according to a second aspect of the present disclosure includes:

a control electrode formed on a base substrate;

an insulation layer adapted to cover the control electrode and formed of an organic insulation material;

a first electrode and a second electrode formed on the insulation layer; and

an active layer formed on at least a portion of the insulation layer located between the first electrode and the second electrode, formed of an organic semiconductor material, and subjected to patterning,

wherein a chemical composition of a surface of a region A that is a region of the insulation layer not formed with the first electrode, the second electrode, and the active layer differs from a chemical composition of a region B that is a region of the insulation layer located under the first electrode, the second electrode, and the active layer.

In order to achieve the above object, an electronic device according to a third aspect of the present disclosure includes:

an insulation layer formed on a base substrate and formed of an organic insulation material;

an active layer formed on the insulation layer, formed of an organic semiconductor material, and subjected to patterning;

a first electrode and a second electrode formed on a portion of the active layer;

an interlayer insulation layer adapted to cover the first electrode, the second electrode, and the active layer; and

a control electrode formed on the interlayer insulation layer and facing the active layer,

wherein a chemical composition of a surface of a region A that is a region of the insulation layer not formed with the active layer differs from a chemical composition of a region B that is a region of the insulation layer located under the active layer.

In order to achieve the above object, an electronic device according to a fourth aspect of the present disclosure includes:

an insulation layer formed on a base substrate and formed of an organic insulation material;

a first electrode and a second electrode formed on the insulation layer;

an active layer formed on a portion of the insulation layer located between the first electrode and the second electrode, formed of an organic semiconductor material, and subjected to patterning;

an interlayer insulation layer adapted to cover the first electrode, the second electrode, and the active layer; and

a control electrode formed on the interlayer insulation layer and facing the active layer,

wherein a chemical composition of a surface of a region A that is a region of the insulation layer not formed with the first electrode, the second electrode, and the active layer differs from a chemical composition of a region B that is a region of the insulation layer located under the first electrode, the second electrode, and the active layer.

In order to achieve the above object, a manufacturing method of an electronic device according to a first aspect of the present disclosure includes respective steps of:

forming a control electrode on a base substrate;

forming an insulation layer formed of an organic insulation material and adapted to cover the control electrode;

subsequently forming, on the insulation layer, an active layer formed of an organic semiconductor material and subjected to patterning, and then

forming a first electrode and a second electrode on the active layer,

wherein, at the time of patterning the active layer, a chemical composition of a surface of a region A that is a region of the insulation layer not formed with the active layer is made to differ from a chemical composition of a region B that is a region of the insulation layer located under the active layer.

In order to achieve the above object, a manufacturing method of an electronic device according to a second aspect of the present disclosure includes respective steps of:

forming a control electrode on a base substrate;

forming an insulation layer formed of an organic insulation material and adapted to cover the control electrode; and

subsequently forming a first electrode and a second electrode on the insulation layer; and then

forming, on at least a portion of the insulation layer located between the first electrode and the second electrode, an active layer formed of an organic semiconductor material and subjected to patterning,

wherein, at the time of patterning the active layer, a chemical composition of a surface of a region A that is a region of the insulation layer not formed with the first electrode, the second electrode, and the active layer is made to differ from a chemical composition of a region B that is a region of the insulation layer located under the first electrode, the second electrode, and the active layer.

In order to achieve the above object, a manufacturing method of an electronic device according to a third aspect of the present disclosure includes respective steps of:

forming an insulation layer formed of an organic insulation material on a base substrate;

subsequently forming, on the insulation layer, an active layer formed of an organic semiconductor material and subject to patterning;

forming a first electrode and a second electrode on a part of the active layer;

subsequently forming an interlayer insulation layer adapted to cover the first electrode, the second electrode, and the active layer; and then

forming a control electrode facing the active layer on the interlayer insulation layer,

wherein, at the time of patterning the active layer, a chemical composition of a surface of a region A that is a region of the insulation layer not formed with the active layer is made to differ from a chemical composition of a region B that is a region of the insulation layer located under the active layer.

In order to achieve the above object, a manufacturing method of an electronic device according to a fourth aspect of the present disclosure includes respective steps of:

forming an insulation layer formed of an organic insulation material on a base substrate;

subsequently forming a first electrode and a second electrode on the insulation layer;

forming, on a portion of the insulation layer located between the first electrode and the second electrode, an active layer formed of an organic semiconductor material and subjected to patterning;

subsequently forming an interlayer insulation layer adapted to cover the first electrode, the second electrode, and the active layer; and then

forming a control electrode facing the active layer on the interlayer insulation layer,

wherein, at the time of patterning the active layer, a chemical composition of a surface of a region A that is a region of the insulation layer not formed with the first electrode, the second electrode, and the active layer is made to differ from a chemical composition of a region B that is a region of the insulation layer located under the first electrode, the second electrode, and the active layer.

### Effects of the Invention

In the electronic devices and the manufacturing methods thereof according to the first to fourth aspects of the present disclosure, the chemical composition of the surface of the region A of the insulation layer differs from the chemical composition of the region B of the insulation layer, or the chemical composition of the surface of the region A of the insulation layer is made to differ from the chemical composition of the region B of the insulation layer. Therefore, at the time of patterning the organic semiconductor material layer, etching selectivity can be surely secured between the organic semiconductor material constituting the organic semiconductor material layer and the organic insulation material constituting the insulation layer. Note that the effects described in the present specification are only examples, and not limited thereto, and further additional effects may also be provided.

### BRIEF DESCRIPTION OF DRAWINGS

FIGS. 1A, 1B, and 1C are partial schematic cross-sectional views of a base substrate and the like to describe a manufacturing method of an electronic device according to a first embodiment.

FIGS. 2A, 2B, and 2C are partial schematic cross-sectional views of the base substrate and the like to describe the manufacturing method of the electronic device according to the first embodiment, subsequent to FIG. 1C.

FIGS. 3A, 3B, and 3C are partial schematic cross-sectional views of a base substrate and the like to describe a manufacturing method of an electronic device according to a second embodiment.

FIGS. 4A and 4B are partial schematic cross-sectional views of the base substrate and the like to describe the manufacturing method of the electronic device according to the second embodiment, subsequent to FIG. 3C.

FIGS. 5A, 5B, and 5C are partial schematic cross-sectional views of a base substrate and the like to describe a manufacturing method of an electronic device according to a third embodiment.

FIGS. 6A, 6B, and 6C are partial schematic cross-sectional views of the base substrate and the like to describe the manufacturing method of the electronic device according to the third embodiment, subsequent to FIG. 5C.

FIGS. 7A, 7B, and 7C are partial schematic cross-sectional views of a base substrate and the like to describe a manufacturing method of an electronic device according to a fourth embodiment.

FIGS. 8A and 8B are partial schematic cross-sectional views of the base substrate and the like to describe the manufacturing method of the electronic device according to the fourth embodiment, subsequent to FIG. 7C.

FIGS. 9A and 9B are partial schematic cross-sectional views illustrating an electronic device according to a seventh embodiment.

FIGS. 10A and 10B are partial schematic cross-sectional views illustrating an electronic device according to the seventh embodiment.

### MODE FOR CARRYING OUT THE INVENTION

In the following, the present disclosure will be described with reference to the drawing on the basis of embodiments, but note that the present disclosure is not limited to the embodiments and various values and materials provided in the embodiments are examples. Note that a description will be provided in the following order.

1. Description for Electronic Devices According to First to Fourth Aspects of Present Disclosure, Manufacturing Methods of Electronic Devices According to First to Fourth aspects of Present Disclosure, and General Information Thereof

2. First Embodiment (Electronic Device and Manufacturing Method Thereof According to First Aspect of Present Disclosure: Bottom Gate/Top Contact Type)

3. Second Embodiment (Electronic Device and Manufacturing Method Thereof According to Second Aspect of Present Disclosure: Bottom Gate/Bottom Contact Type)

4. Third Embodiment (Electronic Device and Manufacturing Method Thereof According to Third Aspect: Top Gate/Top Contact Type)

5. Fourth Embodiment (Electronic Device and Manufacturing Method Thereof According to Fourth Aspect of Present Disclosure: Top Gate/Bottom Contact Type)

6. Fifth Embodiment (Modification of First to Fourth Embodiments)

7. Sixth Embodiment (Modification of First to Fifth Embodiments)

8. Seventh Embodiment (Modification of First to Sixth Embodiments)

9. Eighth Embodiment (Two-Terminal Electronic Device) and Others

[Description for Electronic Devices According to First to Fourth Aspects of Present Disclosure, Manufacturing Methods of Electronic Devices According to First to Fourth Aspects of Present Disclosure, and General Information Thereof]

In electronic devices and the like according to first to second aspects of the present disclosure, a form in which an insulation film is formed between a base substrate, a control electrode, and an insulation layer may be adopted. Furthermore, in electronic devices and the like according to third to fourth aspects of the present disclosure, a form in which an insulation film is formed between a base substrate and an insulation layer may be adopted.

Additionally, in manufacturing methods of the electronic devices according to the first to fourth aspects of the present disclosure, etching gas is reacted with an organic insulation material constituting a region A of the insulation layer at the time of patterning an active layer on the basis of the dry etching method, thereby achieving a form in which a chemical composition of a surface of the region A of the insulation layer is made to differ from a chemical composition of a region B of the insulation layer. Alternatively, a surface layer of the region A of the insulation layer is removed at the time of patterning the active layer on the basis of dry etching method, thereby achieving a form in which the chemical composition of a surface of the region A of the insulation layer is made to differ from the chemical composition of a region B of the insulation layer. Furthermore, in the manufacturing methods of the electronic devices according to the first to fourth aspects of the present disclosure including the above-described preferable forms, a form in which a surface layer of the region A of the insulation layer is removed after patterning the active layer may be achieved.

The electronic device according to the first aspect of the present disclosure including the above-described preferable form, and the electronic device obtained by the manufacturing method of the electronic device according to the first aspect of the present disclosure including the above-above-described preferable form will be collectively referred to as “an electronic device and the like according to the first aspect of the present disclosure” in the following. Furthermore, the electronic device according to the second aspect of the present disclosure including the above-described preferable form, and the electronic device obtained by the manufacturing method of the electronic device according to the second aspect of the present disclosure including the above-described preferable form will be collectively referred to as “an electronic device and the like according to the second aspect of the present disclosure” in the following. Moreover, the electronic device according to the third aspect of the present disclosure including the above-described preferable form, and the electronic device obtained by the manufacturing method of the electronic device according to the third aspect including the above-described preferable form will be collectively referred to as “an electronic device and the like according to the third aspect of the present disclosure” in the following. Also, the electronic device according to the fourth aspect of the present disclosure including the above-described preferable form, and the electronic device obtained by the manufacturing method of the electronic device according to the fourth aspect of the present disclosure including the above-described preferable form will be collectively referred to as “an electronic device and the like according to the fourth aspect of the present disclosure” in the following.

In the electronic devices and the like according to the first to fourth aspects of the present disclosure including the above preferable forms, a form in which a second insulation layer is formed between the active layer and the region B of the insulation layer may be adopted. As a thickness of the second insulation layer, 1×10⁻⁸ m to 5×10⁻⁸ m may be exemplified.

Furthermore, in the electronic devices and the like according to the first to fourth aspects of the present disclosure including the above-described various kinds of preferable forms, a level difference between the surface of the region A of the insulation layer and a surface of the region B of the insulation layer is desirably 2×10⁻⁷ m or less, preferably 5×10⁻⁸ m or less, more preferably 1×10⁻⁸ m or less.

Furthermore, in the electronic devices and the like according to the first to fourth aspects of the present disclosure including the above-described various kinds of preferable various forms, a form in which an oxygen content concentration in the region A of the insulation layer is higher than an oxygen content concentration in the region B of the insulation layer is preferable.

Moreover, in the electronic devices and the like according to the first to fourth aspects of the present disclosure including the above-described various kinds of preferable various forms, the insulation layer may have a composition in which a metallic atom is included in constituent atoms. Furthermore, in this case, the surface of the region A of the insulation layer may have a composition in which a metal oxide obtained by binding oxygen with the metallic atom constituting the insulation layer is included. Additionally, in this composition, the organic insulation material preferably has a composition formed of: silicone resin including copolymer crosslinked polymer and graft copolymer crosslinked polymer (metallic atom as a constituent atom of the insulation layer: Si); silicon germanium polymer including polysilane and polygermane (metallic atoms as constituent atoms of the insulation layer; Si, Ge); silsesquioxane (metallic atom as a constituent atom of the insulation layer: Si); stanniferous polymer (metallic atom as a constituent atom of the insulation layer: Sn); cobaltiferous polymer (metallic atom as a constituent atom of the insulation layer: Co); at least one kind of insulation material selected from a group formed of polymer materials including a metallic atom in a main chain or a side chain of a, b-unsaturated carbene, or has a composition of the organic insulation material preferably has a composition formed of mixture of any one of the above-mentioned materials with at least one kind of resin selected from a group formed of a polyvinyl-phenol resin, a polymide resin, a novolac resin, a cinnamate resin, an acrylic resin, an epoxy resin, a styrene resin, and a polyparaxylylene resin. As a forming method of the insulation layer formed of the organic insulation material, various kinds of coating methods described later may be exemplified.

Alternatively, in the electronic devices and the like according to the first to fourth aspects of the present disclosure including the above-described various kinds of preferable forms, the organic insulation material may have a composition formed of a material in which metal oxide nanoparticles (Metallic insulator nanoparticles are contained. It is similarly applied in the following description) are dispersed inside a polymer material. Here, as the metal oxide nanoparticle, a titanium oxide nanoparticle, a silicon oxide nanoparticle, a vanadium oxide nanoparticle, and an aluminum oxide nanoparticle may be exemplified, and as a particle diameter, 4×10⁻⁷ m or less, preferably, 1×10⁻⁷ m or less may be exemplified. As the polymer material, polymeric materials such as a phenol resin, a polyvinyl phenol resin, a polymide resin, a novolac resin, a cinnamate resin, an acrylic resin, an epoxy resin, a styrene resin, a polyparaxylylene resin, and a fluorine resin may be exemplified, and furthermore, cyclic cycloolefin polymer or cyclic cycloolefin copolymer [more specifically, TOPAS manufactured by Topas Advanced Polymers GmbH, registered trademark), ARTON (manufactured by JSR Corporation, registered trademark), and ZEONOR (manufactured by Zeon Corporation, registered trademark) may be exemplified. As a forming method of the insulation layer in which the metal oxide nanoparticles are dispersed in the polymer material, the various kinds of coating methods described later may be exemplified.

As for a chemical composition, a ratio of constituent elements and a chemical bonding state can be analyzed on the basis of an energy dispersive x-ray spectrometry (EDX) method, an x-ray photoelectron spectroscopy (XPS) method, an Auger electron spectroscopy (AES) method, an ultraviolet photoelectron spectroscopy (UPS) method, and a time-of-flight secondary ion mass spectrometry (F-SIMS) method.

An image display device including the electronic device of the present disclosure includes a semiconductor device formed of the electronic devices according to the first to fourth aspects, wherein

a control electrode in the electronic device corresponds to a gate electrode in the semiconductor device,

an insulation layer or an interlayer insulation layer in the electronic device corresponds to a gate insulation layer in the semiconductor device, and

a first electrode and a second electrode in the electronic device correspond to source/drain electrodes in the semiconductor device.

Furthermore, a sensor is formed of the electronic device according to the first aspect or the second aspect of the present disclosure.

In the electronic devices and the like according to the first to fourth aspects of the present disclosure (hereinafter may be collectively referred to as simply “electronic device and the like of the present disclosure”), examples of the organic semiconductor material constituting the active layer may include polypyrrole and derivatives thereof; polythiophene and derivatives thereof; isothianaphthenes such as polyisothianaphthene; chenylene vinylenes such as polychenylene vinylene; poly (p-phenylenevinylenes) such as poly (p-phenylenevinylene); polyaniline and derivatives thereof; polyacetylenes; polydiacetylenes; polyazulenes; polypyrenes; polycarbazoles; polyselenophenes; polyfurans; poly (p-phenylenes); polyindoles; polypyridazines; polymers such as polyvinyl carbazole, polyphenylene sulfide, and polyvinylene sulfide; polycyclic condensate; and the like. Alternatively, oligomers having the same repeating unit as the above polymers may be exemplified, too. Alternatively, the examples of the organic semiconductor material may include an acenes such as naphthacene, pentacene [2, 3, 6, 7-dibenzoanthracene] and derivatives thereof, anthracene derivatives, oligothiophene derivatives, hexacene, heptacene, dibenzopentacene, tetrabenzopentacene, pyrene, benzopyrene, dibenzopyrene, chrysene, perylene, coronene, terylene, ovalene, quaterrylene, and circumanthracene, and derivatives in which part of carbon atoms of the acenes is substituted with a functional group such as N atoms, S atoms, and O atoms, or a carbonyl group (dioxaanthanthrene compounds including peri-xanthenoxanthene and its derivatives, triphenodioxazine, triphenodithiazine, hexacene-6, 15-quinone, peri-xanthenoxanthene [PXX, 6, 12-dioxaanthanthrene, etc.) and derivatives in which hydrogen atoms of these are substituted with another functional group. Alternatively, the examples of the organic semiconductor material may include thiophene represented by dinaphthothienothiophene (DNTT); condensed polycyclic compound such as a selenophene ring, a benzene ring and derivatives thereof; metal phthalocyanines represented by copper phthalocyanine; tetrathiapentalene and derivatives thereof; tetracarboxylic acid diimides such as naphthalene 1, 4, 5, 8-tetracarboxylic acid diimide, N,N′-bis (4-trifluoromethylbenzyl) naphthalene 1, 4, 5, 8-tetracarboxylic acid diimide, N, N′-bis (1H, 1H-perfluorooctyl), N, N′-bis (1H, 1H-perfluorobutyl), and N, N′-dioctylnaphthalene 1, 4, 5, 8-tetracarboxylic acid diimide derivatives; naphthalene tetracarboxylic acid diimides such as naphthalene 2, 3, 6, 7-tetracarboxylic acid diimide; condensed ring tetracarboxylic acid diimides such as anthracene tetracarboxylic acid diimides such as anthracene, 2, 3, 6, 7-tetracarboxylic acid diimide; fullerenes such as C60, C70, C76, C78, C84 and derivatives thereof; carbon nanotubes such as SWNT; and a such as a merocyanine pigment and a hemicyanine pigment, and derivatives thereof, and the like. Alternatively, the examples of the organic semiconductor material may include poly-3-hexylthiophene (P3HT) in which a hexyl group is introduced into polythiophene, polyanthracene, triphenylene, polyellurophene, polynaphthalene, polyethylenedioxythiophene, poly (3, 4-ethylendioxythiophene)/polystyrenesulfonic acid (PEDOT/PSS), and quinacridone. Alternatively, the examples of the organic semiconductor material may include a compound selected from a group formed of condensed polycyclic aromatic compounds, porphyrin derivatives, phenyl vinylidene-based conjugated oligomers, and thiophene-based conjugated oligomers. Specifically, the examples of the organic semiconductor material may include condensed polycyclic aromatic compound such as acene-based molecules (pentacene, tetracene etc.), porphyrin molecules, and conjugated oligomers (phenyl vinylidene-based or thiophene-based). Alternatively, the examples of the organic semiconductor material may include porphyrin, 4, 4′-biphenyldithiole (BPDT), 4, 4′-diisocyanobiphenyl, 4, 4′-diisocyano-p-terphenyl, 2, 5-bis (5′-thioacetyl-2′-thiophenyl) thiophene, 2, 5-bis (5′-thioacetyl-2′-thiophenyl) thiophene, 4, 4′-diisocyanophenyl, benzidine (biphenyl-4-4′-diamine), TCNQ (tetracyanoquinodimethane), tetrathiafulvalene (TTF), charge-transfer complexes represented by a tetrathiafulvalene (TTF)-TCNQ complex, a bisethylenetetrathiafulvalene (BEDTTTF)-perchloric acid complex, a BEDTTTF-iodine complex, and a TCNQ-iodine complex, biphenyl-4, 4′-dicarboxylic acid, 1,4-di (4-thiophenylacetylinyl)-2-ethylbenzene, 1, 4-di (4-isocyanophenylacetylinyl)-2-ethylbenzene, dendrimer, 1, 4-di (4-thiophenylethyl)-2-ethylbenzene, 2, 2″-dihydroxy-1, 1′: 4′,1″-terphenyl, 4, 4′-biphenyldiethanal, 4, 4′-biphenyldiol, 4, 4′-biphenylisocyanate, 1, 4-diacetylbenzene, diethylbiphenyl-4, 4′-dicarboxylate, benzo [1, 2-c; 3, 4-c′; 5, 6-c″] tris [1, 2] dithiol-1, 4, 7-trithion, α-sexithiophene, tetrathiotetracene, tetraselenotetracene, tetratelluric tetracene, poly(3-alkylthiophene), poly (3-thiophene-β-ethane sulfonic acid), poly (N-alkylpyrrole) poly (3-alkylpyrrole), poly (3, 4-dialkylpyrrole), poly (2, 2′-thienylpyrrole), and poly (dibenzothiophene sulfide).

The organic semiconductor material may also include polymer depending on necessity. The polymer may be dissolved in organic solvent. Specifically, polystyrene, poly-alpha-methylstyrene, and polyolefin may be exemplified as the polymer (organic binder, binder). Furthermore, as the case may be, additives (e.g., so-called doping materials such as n type impurities and p type impurities) may also be added.

As a forming method of the active layer, the coating method may be exemplified in addition to various kinds of physical vapor deposition methods (PVD methods) including a resistance heating deposition method, a sputtering method, a vapor deposition method. Here, as the coating method, examples may include various printing methods such as a screen printing method, an ink jet printing method, an offset printing method, a reverse offset printing method, a gravure printing method, a gravure offset printing method, relief printing, flexo printing, and a micro contact method; a spin coating method; various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit coater method, a slit orifice coater method, a calender coater method, a casting method, a capillary coater method, a bar coater method, and a dipping method; a spray method; a method using a dispenser; and a method that coats a wet mat such as a stamp method.

Furthermore, as a patterning method of the active layer, a dry etching method (reactive ion etching method, RIE method) using oxygen gas (O₂ gas) may be exemplified. In the case of defining that ER₁ is an etching rate of the organic semiconductor material constituting the active layer by the dry etching method using oxygen gas and defining, and ER₂ is an etching rate of an insulation layer by the dry etching method using oxygen gas under the same condition, preferably, ER₁/ER₂≧10 is satisfied.

As a material to constitute the base substrate, examples may include a plastic film, a plastic sheet, and a plastic substrate having flexibility formed of organic polymers such as polymethyl methacrylate (polymethyl methacrylate PMMA), polyvinyl alcohol (PVA), polyvinyl phenol (PVP), polyethersulfone (PES), polyimide, polycarbonate (PC), polyethylene terephthalate (PET), and polyethylene naphthalate (PEN), polyethyl ether ketone, polyolefin. Or, mica may be exemplified. In the case of using the base substrate formed of the above-described organic polymer or polymeric material having flexibility, for example, the electronic device can be embedded or integrated into an image display device and an electronic apparatus having a curved surface shape. As the case may be, the examples as the base substrate may include various kinds of glass substrates, various kinds of glass substrates each having a surface formed with an underlaying insulation film, a quartz substrate, a quartz substrate having a surface formed with an underlaying insulation film, a silicon substrate having a surface formed with an underlaying insulation film, a sapphire substrate, a metal substrate formed of an alloy of various metals or various kinds of metals, such as stainless steel, aluminum, and nickel, a metal foil, and paper. The base substrate may be disposed on a support member (or above the support member) suitably selected from the above-described materials. As the support member, another example may be a conductive substrate (a substrate formed of a metal such as gold and aluminum, a substrate formed of highly-oriented graphite, a stainless steel substrate, and the like). A functional film such as a buffer layer in order to improve adhesive properties and flatness and a barrier film in order to improve gas barrier properties may also be formed on the above-described base substrate.

As materials constituting the first electrode and the second electrode, examples may include copper (Cu), gold (Au), molybdenum (Mo), titanium (Ti), aluminum (Al), nickel (Ni), platinum (Pt), silver (Ag), palladium (Pd). Also, a stacking structure of a layer formed of any one of these materials or a transparent conductive oxide material such as ITO, IZO or AZO may be exemplified.

As materials constituting the control electrode and a wire provided as required, examples may include gold (Au), platinum (Pt), silver (Ag), palladium (Pd), tungsten (W), tantalum (Ta), molybdenum (Mo), aluminum (Al), chromium (Cr), titanium (Ti), copper (Cu), nickel (Ni), indium (In), tin (Sn), iron (Fe), cobalt (Co), zinc (Zn), magnesium (Mg), manganese (Mn), ruthenium (Rh), rubidium (Rb), or an alloy including these metal elements, conductive particles formed of these metals, conductive particles of alloys including the metals, and conductive substances such as polysilicon including impurities. Also, a stacking structure of layers including the elements may be exemplified. Moreover, organic materials (conductive polymers) such as poly (3, 4-ethylenedioxythiophene)/(polystyrene sulfonate) [PEDOT/PSS], TTF-TCNQ, and polyaniline may also be exemplified.

As a forming method of the control electrode, first electrode, second electrode, and the like, examples may include various kinds of PVD methods, various kinds of chemical vapor deposition methods (CVD methods) including a pulsed laser deposition method (PLD), an arc discharge method, and a MOCVD method, a liftoff method, a shadow mask method, and the above various kinds of coating methods using ink or paste. Also, the electrodes may also be formed by a plating method such as an electrolytic plating method or an electroless plating method. Moreover, depending on necessity, a patterning technique may also be combined. Additionally, as the PVD method, examples may include: (a) various kinds of vacuum deposition methods such as an electron beam heating method, a resistance heating method, a flash deposition, a method of heating a crucible; (b) a plasma deposition method; (c) various kinds of sputtering methods such as a bipolar sputtering method, a direct-current sputtering method, a direct-current magnetron sputtering method, a high-frequency sputtering method, a magnetron sputtering method, an ion beam sputtering method, and a bias sputtering method; and (d) various kinds of ion plating methods such as a direct current (DC) method, an RF method, a multi-cathode method, an activated reaction method, an electric field deposition method, a high-frequency ion plating method, and a reactive ion plating method. In the case of forming the control electrode, first electrode, and second electrode on the basis of the etching method, a dry etching method or a wet etching method may be adopted, and as the dry etching method, ion milling and reactive ion etching (RIE) may be exemplified. Furthermore, the control electrode and the like may also be formed on the basis of a laser ablation method, a mask deposition method, a laser transfer method, and the like.

An inorganic insulation material and an organic insulation material may be exemplified as materials constituting the insulation film, second insulation layer, and interlayer insulation layer. As the inorganic insulation material, materials such as a silicon oxide material, silicon nitride (SiN_{Y}), aluminum oxide (Al₂O₃), titanium oxide, and hafnium oxide HfO₂ may be exemplified. Here, as the silicon oxide material, examples may include silicon oxide (SiOₓ), BPSG, PSG, BSG, AsSG, PbSG, silicon oxynitride (SiON), Spin On Glass (SOG), and low-dielectric constant SiO₂ based materials (e.g., polyarylether, cycloperfluorocarbon polymer and benzocyclobutene, cyclic fluorine resins, polytetrafluoroethylene, arylether fluoride, fluorinated polyimide, amorphous carbon, organic SOG). As a method of forming the insulation layer formed of the inorganic insulation material, examples may include the above-described various kinds of coating methods, and vacuum processes such as the above-described various kinds of PVD methods and CVD method. Alternatively, a sol-gel method using solution in which these inorganic insulation materials are dissolved, a liftoff method, an electrodeposition method, and a shadow mask method may be exemplified. Also, depending on necessity, combination of any of these forming methods with the patterning technique may also be exemplified. On the other hand, as the organic insulation material, examples may include polymeric materials such as a phenolic resin, a polyvinylphenol resin, a polyimide resin, a novolac resin, a cinnamate resin, an acrylic resin, an epoxy resin, a styrene resin, a polyparaxylylene resin, and also a fluorine resin. Also, cyclic cycloolefin polymers or cyclic cycloolefin copolymers [specifically, TOPAS, ARTON, and ZEONOR manufactured by Zeon Corporation, registered mark)] may be exemplified. As a forming method of the insulation layer formed of the organic insulation material, the above-mentioned various kinds of coating methods may be exemplified, and also the vacuum processes such as PVD methods and CVD methods may be used.

The insulation film and the interlayer insulation layer may also be subjected to patterning on the basis of a known method such as the wet etching method, dry etching method, and laser ablation method depending on necessity.

The electronic device of the present disclosure may have a so-called three-terminal structure or a two-terminal structure. For example, a field-effect transistor, more specifically, a thin-film transistor (TFT) is formed or a light emitting element is formed by the electronic device having the three-terminal structure. In other words, a light emitting element (organic light emitting element, organic light emitting transistor) in which an active layer emits light by applying voltage to the control electrode, first electrode, and second electrode can be formed. In these electronic devices, current flowing in the active layer from the first electrode to the second electrode is controlled by the voltage applied to the control electrode. Here, whether the electronic device exhibits a function as a field-effect transistor or as a light emitting element depends on a state (bias) of voltage application to the first and second electrodes. First, the control electrode is modulated after bias is applied in a range where electrons are not injected from the second electrode, thereby causing current to flow from the first electrode to the second electrode. This is a transistor operation. On the other hand, when the bias to the first electrode and the second electrode is increased after positive holes are sufficiently accumulated, electron injection starts and light is emitted by recombination with the positive holes. Further, as an electronic device having the two-terminal structure, a photoelectric conversion element in which current flows between the first electrode and the second electrode by light irradiation on the active layer may be exemplified.

As a sensor, a light sensor and a photoelectric conversion element (specifically, solar cell or image sensor) may be exemplified. Specifically, as an organic semiconductor molecules constituting an active layer of an optical sensor, a dye which absorbs light (including not only visible light but also ultraviolet light and infrared light) may be used. Furthermore, in the photoelectric conversion element, current flows between the first electrode and the second electrode by irradiating the active layer with the light (including not only visible light but also ultraviolet light and infrared light). Meanwhile, the photoelectric conversion element may also be formed of an electronic device having the three-terminal structure. In this case, voltage application to the control electrode may not necessarily be performed or may be performed. In the latter case, flowing current can be modulated by applying voltage to the control electrode. Also, as the sensor, a chemical substance sensor may be exemplified. The chemical substance sensor is adapted to measure an amount (concentration) of a chemical substance adsorbed on the active layer by making current flow between the first electrode and the second electrode or applying appropriate voltage between the first electrode and the second electrode and measuring an electric resistance value of the active layer, utilizing a fact that the electric resistance value between the first electrode and the second electrode is varied when the chemical substance to be detected is adsorbed to the active layer. Alternatively, a molecular sensor having molecular recognition ability, and a biosensor may be exemplified. The biosensor is prepared by binding and anchoring binding molecules (for example, biomolecules) onto a surface of the active layer and further adding functional molecules (for example, different biomolecules) that interact with the binding molecules. Note that the chemical substance is brought into a state of adsorption equilibrium on the active layer. Therefore, when the amount (concentration) of the chemical substance in an atmosphere where the active layer is placed changes with time, the equilibrium state also changes. As the chemical substance, for example, NO₂ gas, O₂ gas, NH₃ gas, styrene gas, hexane gas, octane gas, decane gas, and trimethylbenzene gas may be exemplified.

As an example to be incorporated with the electronic device of the present disclosure, an image display device may be exemplified although not limited thereto. Here, as the image display device, examples may include various kinds of image display devices (for example, an organic electroluminescence display device, a liquid crystal display device, a plasma display device, an electrophoretic display device, a cold cathode field emission display, or the like) in a so-called desktop personal computer, a notebook-type personal computer, a mobile personal computer, a tablet terminal including a tablet personal computer, a personal digital assist (PDA), a car navigation system, a cellular phone and a smartphone, a game machine, an electronic book, an electronic paper such as an electronic newspaper, a bulletin substrate such as a sign, a poster, and a blackboard, a rewritable paper alternative to a paper for a copy machine and a printer, calculators, a display unit of a home electric appliance, a card display unit such as a discount card, an electronic advertisement, and an electronic POP. Additionally, various kinds of lighting devices may also be exemplified.

In the case of applying and using the electronic device of the present disclosure to various kinds of electronic apparatuses including an image display device, an electronic paper, a radio frequency identification card (RFIDs) and the like, a monolithic integrated circuit in which a large number of electronic devices are integrated on a supporting member may be applied, or respective electronic devices may be cut and individualized and may be used as a discrete component as well. Additionally, the electronic device may be sealed with a resin.

### FIRST EMBODIMENT

A first embodiment relates to an electronic device according to the first aspect of the present disclosure and a manufacturing method of the electronic device according to the first aspect of the present disclosure, and further relates to an image display device.

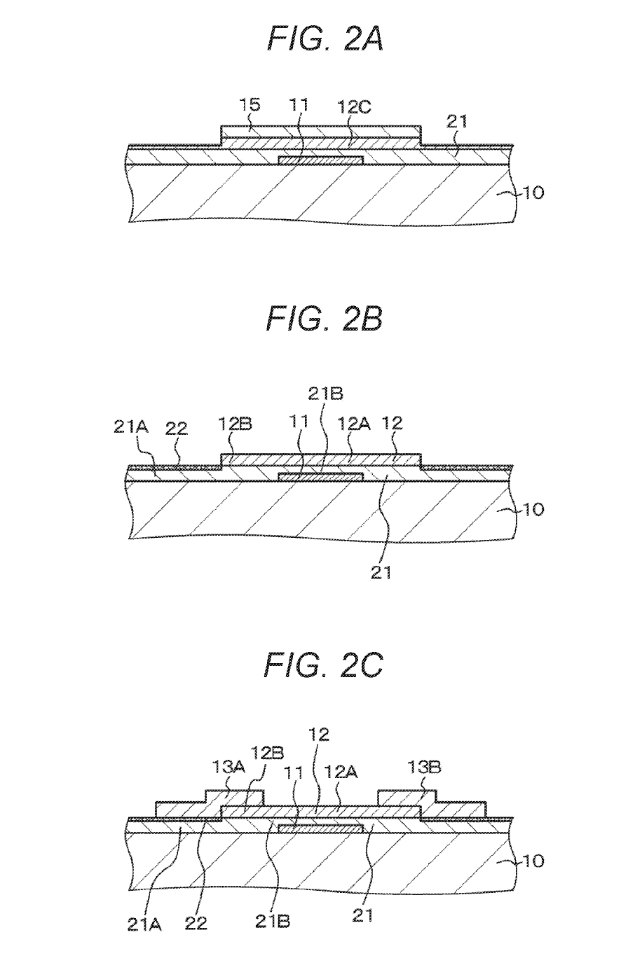

As illustrated in a schematic partial cross-sectional view in FIG. 2C, the electronic device of the first embodiment is a bottom gate/top contact type and also a three-terminal electronic device, specifically, a TFT. The electronic device includes:

(a) a control electrode 11 formed on a base substrate 10;

(b) an insulation layer 21 adapted to cover the control electrode 11 and formed of an organic insulation material;

(c) an active layer 12 formed on the insulation layer 21, formed of an organic semiconductor material, and subjected to patterning; and

(d) a first electrode 13A and a second electrode 13B formed on the active layer 12. Furthermore, a chemical composition of a surface of a region A (21A) that is a region of the insulation layer 21 not formed with the active layer 12 differs from a chemical composition of a region B (21B) that is a region of the insulation layer 21 located under the active layer 12.

Note that, in the following, a description may be provided using a term “gate electrode 11” instead of the “control electrode 11”, the description may be provided using a term “channel forming region 12A and/or channel forming region extending portion 12B” instead of the “active layer 12”, and the description may be provided using a term “source/drain electrodes 13A, 13B” instead of the “first electrode 13A and second electrode 13B”.

Specifically, in the first embodiment or second to eighth embodiments described later, the base substrate 10 is formed of a glass substrate. Meanwhile, the base substrate 10 may also be formed of a plastic substrate. Furthermore, the gate electrode 11 is formed of a stacking structure of aluminum and molybdenum from the base substrate side, and the channel forming region 12A and the channel forming region extending portion 12B are formed of derivatives of peri-xanthenoxanthene (PXX, 6, 12-dioxaanthanthrene), more specifically, ethylphenyl-PXX, and each of the first electrode 13A and the second electrode 13B is formed of a stacking structure of aluminum and molybdenum from the base substrate side.

Furthermore, in the first embodiment or the second to fourth embodiments described later, a metallic atom is included in constituent atoms of the insulation layer 21, and metal oxide obtained by binding oxygen with the metallic atom constituting the insulation layer 21 is included in the surface of the region A (21A) of the insulation layer 21. Additionally, the organic insulation material is formed of a thermosetting silicone resin including copolymer crosslinked polymer and graft copolymer crosslinked polymer (metallic atom as the constituent atom of the insulation layer 21: Si). Meanwhile, in the first to second embodiments, the insulation layer 21, particularly, the region B (21B) that is the region of the insulation layer 21 located under the active layer 12 corresponds to a gate insulation layer.

The image display devices of the first to seventh embodiments include semiconductor devices formed of the electronic devices of the first to seventh embodiments.

The control electrode in the electronic device corresponds to the gate electrode 11 in the semiconductor device,

the insulation layer 21 or an interlayer insulation layer 14 in the electronic device corresponds to the gate insulation layer in the semiconductor device,

and the first electrode and the second electrode in the electronic device correspond to the source/drain electrodes 13A, 13B.

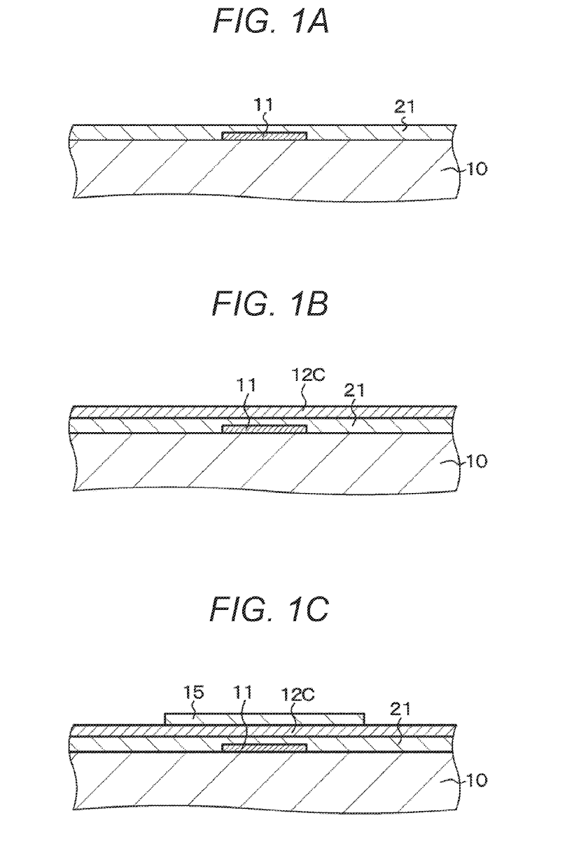

In the following, a manufacturing method of the three-terminal electronic device (bottom gate/top contact TFT) of the first embodiment will be described with reference to FIGS. 1A, 1B, 1C, 2A, 2B and 2C which are schematic partial cross-sectional views of the base substrate and the like. In the manufacturing method of the electronic device in the first embodiment or the second to fourth embodiments described later, etching gas is reacted with the organic insulation material constituting the region A (21A) of the insulation layer 21 at the time of patterning the active layer 12 on the basis of the dry etching method, thereby making the chemical composition of the surface of the region A (21A) of the insulation layer 21 differ from the chemical composition of the region B (21B) of the insulation layer 21.

[Step-100]

First, the control electrode 11 is formed on the base substrate 10. Specifically, the gate electrode 11 and the insulation layer 21 adapted to cover the gate electrode 11 are formed on the base substrate 10. More specifically, an aluminum (Al) layer having a thickness of 50 nm and a molybdenum (Mo) layer having a thickness of 30 nm are sequentially deposited on the base substrate 10 by the sputtering method. Then, the gate electrode 11 can be obtained by patterning the molybdenum layer and the aluminum layer on the basis of a lithography technique and an etching technique. Note that the gate electrode 11 may also be formed on the base substrate 10 on the basis of a printing method depending on a used material.

[Step-110]

After that, the insulation layer 21 formed of the organic insulation material and adapted to cover the control electrode 11 is formed. Specifically, thermosetting silicone resin solution is coated on the base substrate 10 and the gate electrode 11 by a spin coating method, and then heating is performed, thereby obtaining the insulation layer 21 formed of the silicone resin and having a thickness of 0.4 μm. Thus, the structure illustrated in FIG. 1A can be obtained.

[Step-120]

Next, organic semiconductor material solvent (more specifically, solution of ethylphenyl-PXX using toluene as solvent) to constitute the active layer is deposited on the insulation layer 21, and dried at 140° C. Consequently, an organic semiconductor material layer 12C can be formed on the insulation layer 21 (refer to FIG. 1B).

[Step-130]

After that, the active layer 12 (channel forming region 12A having a thickness of 20 nm and the channel forming region extending portion 12B) formed of the organic semiconductor material and subjected to patterning is formed on the insulation layer 21. Specifically, a resist layer 15 is formed by a known method on a region to be formed with a channel forming region 12A and a channel forming region extending portion 12B of the organic semiconductor material layer 12C (refer to FIG. 1C). Then, the active layer 12 (channel forming region 12A and channel forming region extending portion 12B) is patterned on the basis of the dry etching method (RUE method) using oxygen gas (O₂ gas). FIG. 2A is a schematic partial cross-sectional view of the base substrate and the like during patterning, and FIG. 2B is a schematic partial cross-sectional view of the base substrate and the like after the patterning is finished and the resist layer 15 is removed. Thus, at the time of patterning the active layer 12, the chemical composition of the surface of the region A (21A) that is the region of the insulation layer 21 not formed with the active layer 12 is made to differ from the chemical composition of the region B (21B) that is the region of the insulation layer 21 located under the active layer 12.

Here, the organic semiconductor material layer 12C is subjected to the dry etching, and when the insulation layer 21 under the organic semiconductor material layer 12C begins to be exposed, silicon (Si) atoms inside the organic insulation material constituting the exposed insulation layer 21 reacts with oxygen atoms constituting etching gas, and an oxide film 22 formed of SiO_{X} is formed on a surface area of the insulation layer 21. Note that in the case of indicating a metallic atom as a constituent atom of the insulation layer by “M”, the oxide film formed of M_{X}O_{Y}. The oxide film 22 functions as a kind of an etching stopper. As a result, further etching of the insulation layer 21 by oxygen gas is stopped. As a result of the above, the insulation layer 21 can be prevented from being excessively etched, a level difference between the surface of the region A (21A) of the insulation layer 21 and the surface of the region B (21B) of the insulation layer 21 can be suppressed within 2×10⁻⁷ m or less, preferably 5×10⁻⁸ m or less, more preferably, 1×10⁻⁸ m or less (specifically, about 10 nm in the first embodiment). Meanwhile, SiO_{X} is formed in the region A (21A) of the insulation layer 21, and SiO_{X} is not formed on the region B (21B) of the insulation layer 21. Therefore, an oxygen content concentration in the region A (21A) of the insulation layer 21 is higher than an oxygen content concentration in the region B (21B) of the insulation layer 21. The situation is similar in the second to fourth embodiments described later.

[Step-140]

After that, the first electrode 13A and the second electrode 13B are formed on the active layer 12 (specifically, on the channel forming region extending portion 12B). Specifically, the first electrode 13A and the second electrode 13B can be obtained by sequentially forming the aluminum layer and the molybdenum layer on the basis of the sputtering method and then patterning the molybdenum layer and the aluminum layer on the basis of the lithography technique and the etching technique. Thus, the structure illustrated in FIG. 2C can be obtained. Meanwhile, at the time of forming the first electrode 13A and the second electrode 13B, the first electrode 13A and the second electrode 13B can be formed without a photolithography process by covering part of the channel forming region 12A and channel forming region extending portion 12B with a hard mask. Furthermore, the first electrode 13A and the second electrode 13B can be also formed on the basis of the printing method. Aluminum has poor adhesive properties to an organic material and fine process can hardly performed thereon, but has high adhesive properties to the oxide film 22 and fine process can be performed, and high reliability can be provided to the first electrode 13A and the second electrode 13B.

[Step-150]

For example, in manufacturing an image display device, subsequent to this step, the image display device can be manufactured by forming, on the basis of a known method, an image display unit (specifically, an image display unit including, for example, an organic electroluminescence element or an electrophoretic display element, a semiconductor light-emitting element, or the like) on or above the thus obtained TFT that is the electronic device constituting a control unit (pixel driving circuit) of the image display device. Here, the thus obtained electronic device constituting the control unit (pixel driving circuit) of the image display device and an electrode (for example, a pixel electrode) in the image display unit may be connected via a connecting portion such as a contact hole or a wire. Alternatively, a passivation film (not shown) is formed over an entire surface. Thus, the bottom gate/top contact electronic device (FET, specifically, TFT) can be obtained. Alternatively, after the channel forming region extending portion 12B is subjected to patterning, a passivation film (not shown) may be formed over the entire surface. The above-described steps can be also applied to second to seventh embodiments described later.

In the first embodiment, the chemical composition of the surface of the region A of the insulation layer differs from the chemical composition of the region B of the insulation layer, or the chemical composition of the surface of the region A of the insulation layer is made to differ from the chemical composition of the region B of the insulation layer. Therefore, etching selectivity between the organic semiconductor material constituting the organic semiconductor material layer and the organic insulation material constituting the insulation layer can be surely secured at the time of patterning the organic semiconductor material layer. Furthermore, at the time of etching the organic semiconductor material layer, the insulation layer can be prevented from being excessively etched by the etching gas without any extra process, and the level difference between the surface of the region A of the insulation layer and the surface of the region B of the insulation layer can be eliminated or reduced. Therefore, various kinds of problems such as line disconnection, ununiformity within the surface, insufficient coverage, and ununiform film thickness do not occur, and current leakage can be reduced. Moreover, problems such as degradation of reliability of the electronic device, occurrence of failure, limitation of layout in the electronic device, and the like do not occur. Additionally, since the region B of the insulation layer is prevented from being exposed to the etching gas, an interface between the active layer and the insulation layer is kept in a state same as when the organic semiconductor material layer is formed on the insulation layer, and performance degradation of the electronic device and the like can be prevented from occurrence.

### SECOND EMBODIMENT

A second embodiment relates to an electronic device according to a second aspect of the present disclosure and a manufacturing method of the electronic device according to the second aspect of the present disclosure, and further relates to an image display device.

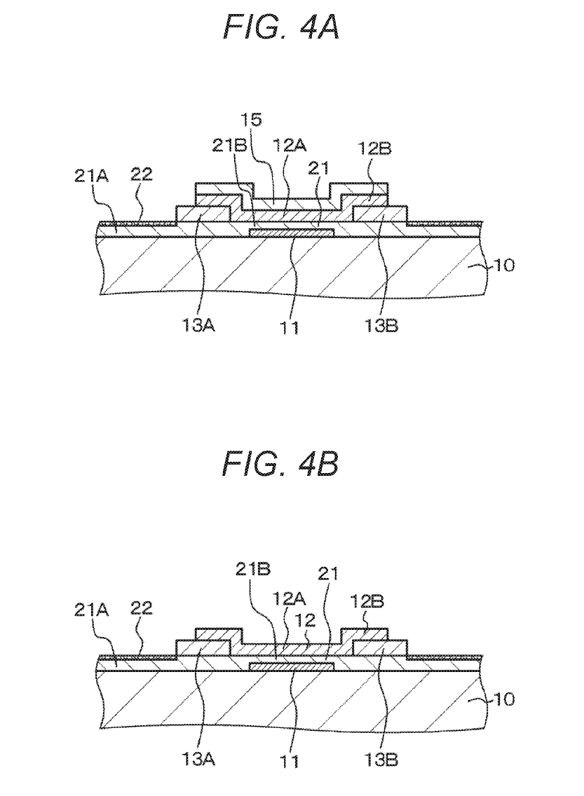

As illustrated in a partial schematic cross-sectional view in FIG. 4B, the electronic device of the second embodiment is a bottom gate/bottom contact type and also a three-terminal electronic device, specifically, a TFT, and includes:

(a) an insulation layer 21 adapted to cover a control electrode 11 and formed of an organic insulation material;

(b) a first electrode 13A and a second electrode 13B formed on the insulation layer 21; and

(c) an active layer 12 formed at least on a portion of the insulation layer 21 located between the first electrode 13A and the second electrode 13B, formed of an organic semiconductor material, and subjected to patterning. Furthermore, a chemical composition of a surface of a region A (21A) that is a region of the insulation layer 21 not formed with the first electrode 13A, second electrode 13B, and active layer 12 differs from a chemical composition of a region B (21B) that is a region of the insulation layer 21 located under the first electrode 13A, second electrode 13B, and active layer 12.

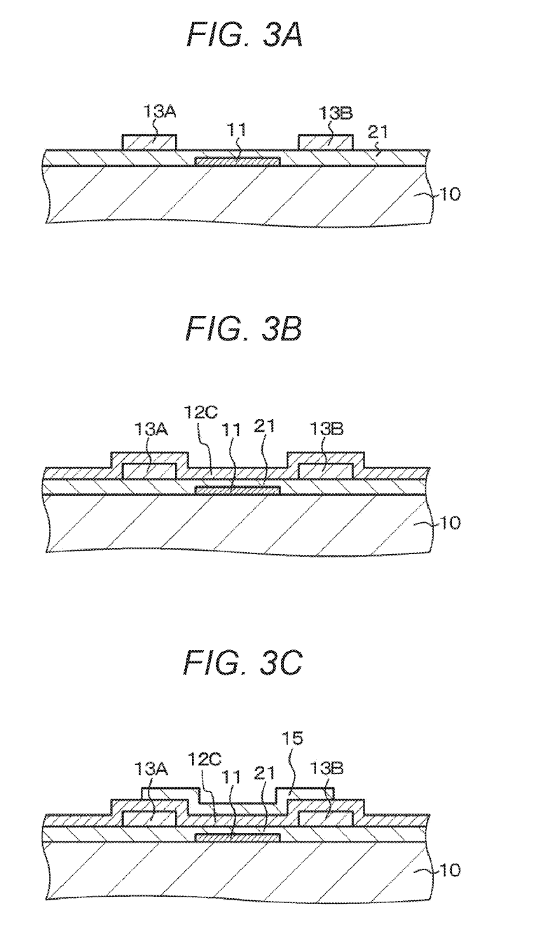

In the following, a manufacturing method of the three-terminal electronic device (bottom gate/bottom contact type TFT) of the second embodiment will be described with references to FIGS. 3A, 3B, 3C, 4A, and 4B which are schematic partial cross-sectional views of a base substrate and the like.

[Step-200]

First, the control electrode 11 is formed on the base substrate 10 and then an insulation layer 21 formed of the organic insulation material and adapted to cover the control electrode 11 is formed. Specifically, processes similar to [Step-100] to [Step-110] in a first embodiment are executed.

[Step-210]

Next, the first electrode 13A and the second electrode 13B are formed on the insulation layer 21 (refer to FIG. 3A). Specifically, a process similar to [Step-140] in the first embodiment is executed.

[Step-220]

After that, the active layer 12 formed of the organic semiconductor material and subjected to patterning is formed at least on the portion of the insulation layer 21 located between the first electrode 13A and the second electrode 13B. Specifically, the patterned active layer 12 is formed on the portion of the insulation layer 21 located between the first electrode 13A and the second electrode 13B. More specifically, similarly to [Step-120] of the first embodiment, an organic semiconductor material layer 12C is formed on an entire surface (refer to FIG. 3B). Next, similarly to [Step-130] of the first embodiment, a resist layer 15 is formed by a known method on a region to be formed with a channel forming region 12A and a channel forming region extending portion 12B of the organic semiconductor material layer 12C (refer to FIG. 3C). Then, the active layer 12 (channel forming region 12A and channel forming region extending portion 12B) is patterned on the basis of a dry etching method using oxygen gas. FIG. 4A is the schematic partial cross-sectional view illustrating the base substrate and the like after patterning, and FIG. 4B is the schematic partial cross-sectional view illustrating the base substrate and the like after removing the resist layer 15. Thus, the chemical composition of the surface of the region A (21A) that is the region of the insulation layer 21 not formed with the first electrode 13A, second electrode 13B, and active layer 12 is made to differ from the chemical composition of the region B (21B) that is the region of the insulation layer 21 located under the first electrode 13A, second electrode 13B, and active layer 12.

The TFT may be completed as described above, or furthermore, the image display device may also be manufactured in a manner similar to [Step-150] of the first embodiment.

### THIRD EMBODIMENT

A third embodiment relates to an electronic device according to a third aspect of the present disclosure and a manufacturing method of the electronic device according to the third aspect of the present disclosure, and further relates to an image display device.

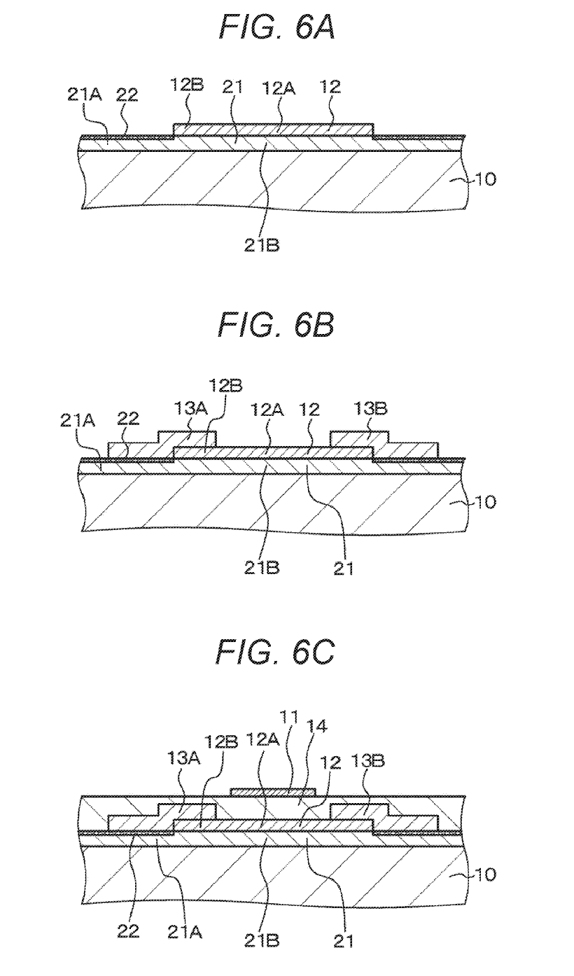

The electronic device of the third embodiment is a top gate/top contact type and also a three-terminal electronic device, specifically, a TFT. As illustrated in a partial schematic cross-sectional view of FIG. 6C, the electronic device includes: an insulation layer 21 formed on a base substrate 10 and formed of an organic insulation material; an active layer 12 formed on the insulation layer 21, formed of an organic semiconductor material, and subjected to patterning; a first electrode 13A and a second electrode 13B formed on a part of the active layer 12; an interlayer insulation layer 14 adapted to cover the first electrode 13A, second electrode 13B, and active layer 12; and a control electrode 11 formed on the interlayer insulation layer 14 and facing the active layer 12. Furthermore, a chemical composition of a surface of a region A (21A) that is a region of the insulation layer 21 not formed with the active layer 12 differs from a chemical composition of a region B (21B) that is a region of the insulation layer 21 located under the active layer 12. Note that the insulation layer 21 is formed for a purpose of flattening and further improving characteristics of the electronic device. Furthermore, in the third to fourth embodiments, the interlayer insulation layer 14 corresponds to a gate insulation layer.

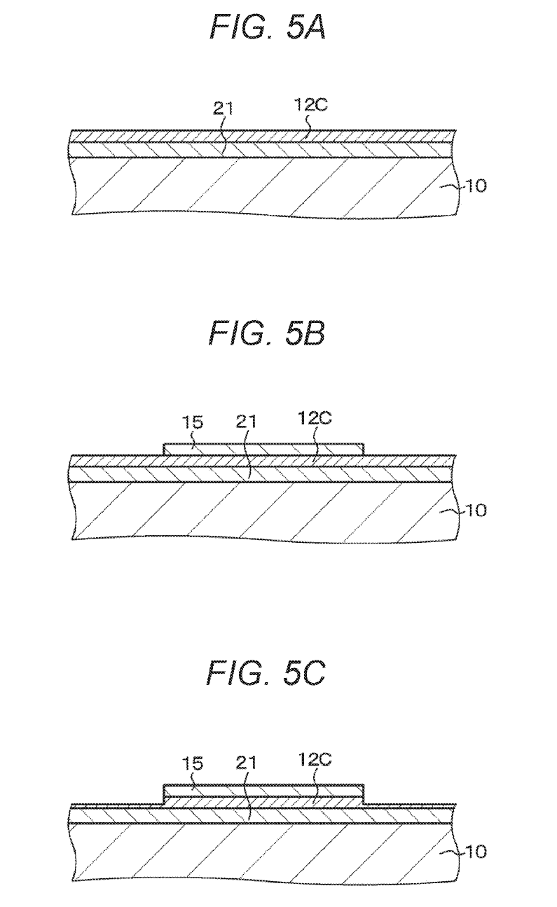

In the following, a manufacturing method of the three-terminal electronic device (top gate/top contact type TFT) of the third embodiment will be described with references to FIGS. 5A, 5B, 5C, 6A, 6B and 6C which are schematic partial cross-sectional views of a base substrate and the like. Meanwhile, the base substrate 10 is formed of a glass substrate in the third embodiment or also in the fourth embodiment described later, but not limited thereto, the base substrate may also be formed of, for example, a plastic substrate.

[Step-300]

First, the insulation layer 21 formed of the organic insulation material is formed on the base substrate 10 in a manner similar to [Step-110] of the first embodiment.

[Step-310]

Next, the active layer 12 formed of the organic semiconductor material and subjected to patterning is formed on the insulation layer 21. Specifically, processes similar to [Step-120] and [Step-130] in the first embodiment are executed. In other words, after forming an organic semiconductor material layer 12C on the insulation layer 21 (refer to FIG. 5A), a resist layer 15 is formed by a known method on a region of the organic semiconductor material layer 12C to be formed with a channel forming region 12A and a channel forming region extending portion 12B (refer to FIG. 5B). Then, the active layer 12 (channel forming region 12A and channel forming region extending portion 12B) is patterned on the basis of a dry etching method using oxygen gas. FIG. 5C is the schematic partial cross-sectional view illustrating the base substrate and the like during patterning, and FIG. 6A is the schematic partial cross-sectional view illustrating the base substrate and the like after the patterning is finished and the resist layer 15 is removed. Thus, at the time of patterning the active layer 12, the chemical composition of the surface of the region A (21A) that is the region of the insulation layer 21 not formed with the active layer 12 is made to differ from the chemical composition of the region B (21B) that is the region of the insulation layer 21 located under the active layer 12.

[Step-320]

After that, the first electrode 13A and the second electrode 13B are formed on a part of the active layer 12, specifically, the channel forming region extending portion 12B in a manner similar to [Step-140] of the first embodiment (refer to FIG. 6B).

[Step-330]

Next, the interlayer insulation layer 14 adapted to cover the first electrode 13A, second electrode 13B, and active layer 12 is formed, and then the control electrode 11 facing the active layer 12 is formed on the interlayer insulation layer 14. Specifically, the interlayer insulation layer (gate insulation layer) 14 formed of cycloperfluorocarbon polymer (manufactured by Asahi Glass Co., Ltd.: Product Name Cytop) is formed on an entire surface. After that, the gate electrode 11 facing the channel forming region 12A is obtained via the interlayer insulation layer (gate insulation layer) 14 in a manner similar to [Step-100] of the first embodiment. Thus, the structure illustrated in FIG. 6C can be obtained.

The TFT may be completed as described above, or furthermore, the image display device may also be manufactured in a manner similar to [Step-150] of the first embodiment.

### FOURTH EMBODIMENT

A fourth embodiment relates to an electronic device according to a fourth aspect of the present disclosure and a manufacturing method of the electronic device according to the fourth aspect of the present disclosure, and further relates to an image display device.

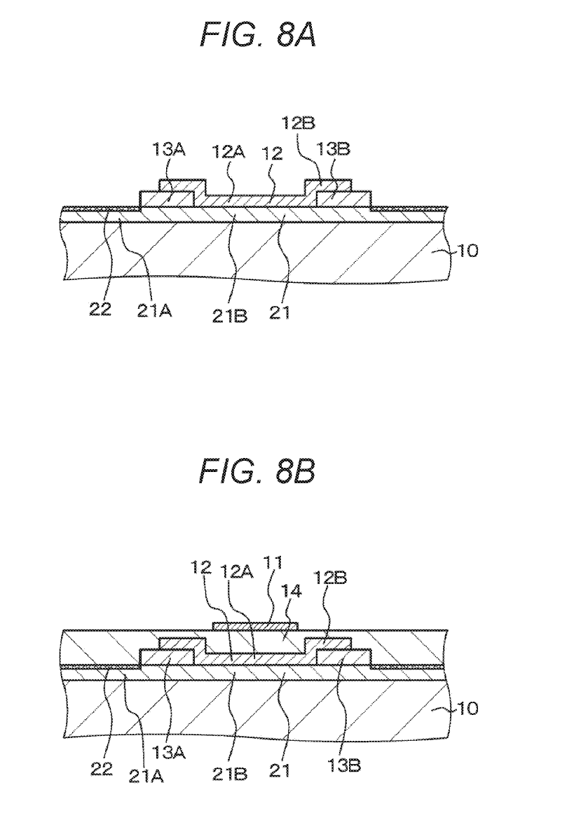

The electronic device of the fourth embodiment is a top gate/bottom contact type and also a three-terminal electronic device, specifically, a TFT. As illustrated in a partial schematic cross-sectional view of FIG. 8B, the electronic device includes: an insulation layer 21 formed on a base substrate 10 and formed of an organic insulation material; a first electrode 13A and a second electrode 13B formed on the insulation layer 21; an active layer 12 formed on a portion of the insulation layer 21 located between the first electrode 13A, second electrode 13B, formed of an organic semiconductor material, and subjected to patterning; an interlayer insulation layer 14 adapted to cover the first electrode 13A, second electrode 13B, and active layer 12; and a control electrode 11 formed on the interlayer insulation layer 14 and facing the active layer 12. Furthermore, a chemical composition of a surface of a region A (21A) that is a region of the insulation layer 21 not formed with the first electrode 13A, second electrode 13B, and active layer 12 differs from a chemical composition of a region B (21B) that is a region of the insulation layer 21 located under the first electrode 13A, second electrode 13B, and active layer 12.

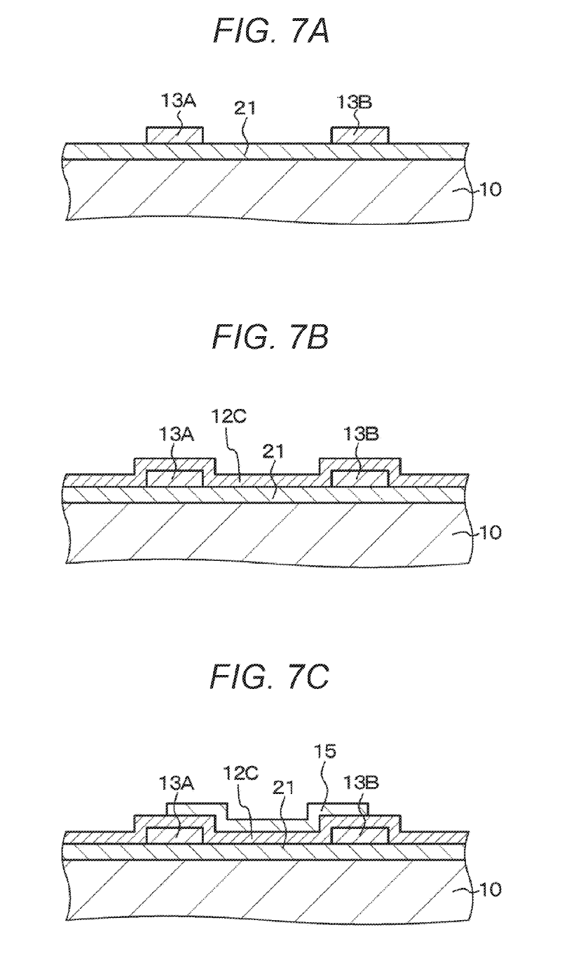

In the following, a manufacturing method of the three-terminal electronic device (top gate/bottom contact type TFT) of the fourth embodiment will be described with references to FIGS. 7A, 7B, 7C, 8A, and 8B which are schematic partial cross-sectional views of a base substrate and the like.

[Step-400]

First, the insulation layer 21 formed of the organic insulation material is formed on the base substrate 10 in a manner similar to [Step-110] of the first embodiment.

[Step-410]

Next, the first electrode 13A and the second electrode 13B are formed on the insulation layer 21 in a manner similar to [Step-140] of the first embodiment (refer to FIG. 7A).

[Step-420]

After that, the active layer 12 formed of the organic semiconductor material and subjected to patterning is formed on the portion of the insulation layer 21 located between the first electrode 13A and the second electrode 13B. Specifically, processes similar to [Step-120] and [Step-130] in the first embodiment are executed. In other words, after forming an organic semiconductor material layer 12C on an entire surface (refer to FIG. 7B), a resist layer 15 is formed by a known method on a region of the organic semiconductor material layer 12C to be formed with a channel forming region 12A and a channel forming region extending portion 12B (refer to FIG. 7C). Then, the active layer 12 (channel forming region 12A and channel forming region extending portion 12B) is patterned on the basis of a dry etching method using oxygen gas. FIG. 8A is a schematic partial cross-sectional view illustrating the base substrate and the like after patterning is finished and the resist layer 15 is removed. Thus, at the time of patterning the active layer 12, the chemical composition of the surface of the region A (21A) that is the region of the insulation layer 21 not formed with the first electrode 13A, second electrode 13B, and active layer 12 is made to differ from the chemical composition of the region B (21B) that is the region of the insulation layer 21 located under the first electrode 13A, second electrode 13B, and active layer 12.

[Step-430]

After that, in a manner similar to [Step-330] of the third embodiment, the interlayer insulation layer 14 adapted to cover the first electrode 13A, second electrode 13B, and active layer 12 is formed, and then the control electrode 11 facing the active layer 12 is formed on the interlayer insulation layer 14. Thus, the structure illustrated in FIG. 8B can be obtained.

The TFT may be completed as described above, or furthermore, the image display device may also be manufactured in a manner similar to [Step-150] of the first embodiment.

### FIRTH EMBODIMENT

The fifth embodiment is a modification of the first to fourth embodiments. In the first to fourth embodiments, a material including metallic atoms in constituent atoms of the insulation layer 21 is used as the material constituting the insulation layer 21. On the other hand, in the fifth embodiment, the organic insulation material is formed of a material in which metal oxide nanoparticles are dispersed in a polymer material (content percentage is 5% to 30% by mass). Here, the polymer material is formed of a thermosetting polyvinylphenol resin (PVP), and the metal oxide nanoparticles are formed of titanium oxide nanoparticles. Furthermore, the active layer 12 is formed of dinaphthothienothiophene (DNTT) having a thickness of 30 nm formed by a vacuum deposition method.

In the fifth embodiment, the insulation layer 21 having a thickness of 0.4 μm and formed of the organic insulation material in which the metal oxide nanoparticles are dispersed in the polymer material is formed in a process similar to [Step-110] of the first embodiment, [Step-200] of the second embodiment, [Step-300] of the third embodiment, and [Step-400] of the fourth embodiment. Then, a surface layer of the region A (21A) of the insulation layer 21 is removed at the time of patterning an active layer 12 on the basis of the dry etching method, thereby making the chemical composition of the surface the region A (21A) of the insulation layer 21 differ from the chemical composition of the region B (21B) of the insulation layer 21 in a process similar to [Step-120] to [Step-130] of the first embodiment, [Step-220] of the second embodiment, [Step-310] of the third embodiment, and [Step-420] of the fourth embodiment. In other words, the active layer 12 formed of the organic semiconductor material and subjected to patterning is formed, but at this point, as soon as etching of the insulation layer 21 is started, the metal oxide nanoparticles are exposed on an uppermost surface of the insulation layer 21. Then, the metal oxide nanoparticles eccentrically located on the uppermost surface of the insulation layer 21 functions as a kind of etching stopper. As a result, dry etching of the insulation layer 21 is not performed any further.

Thus, also in the fifth embodiment, the metal oxide nanoparticles are exposed on the uppermost surface of the insulation layer. As a result, the chemical composition of the surface of the region A of the insulation layer differs from the chemical composition of the region B of the insulation layer, or the chemical composition of the surface of the region A of the insulation layer is made to differ from the chemical composition of the region B of the insulation layer. Therefore, at the time of patterning the organic semiconductor material layer, etching selectivity can be surely secured between the organic semiconductor material constituting the organic semiconductor material layer and the organic insulation material constituting the insulation layer. Furthermore, at the time of etching the organic semiconductor material layer, the insulation layer can be prevented from being excessively etched by the etching gas without any extra process, and the level difference between the surface of the region A of the insulation layer and the surface of the region B of the insulation layer can be eliminated or reduced. Therefore, various kinds of problems such as line disconnection, ununiformity within the surface, insufficient coverage, and ununiform film thickness do not occur, and current leakage can be reduced. Moreover, problems such as degradation of reliability of the electronic device, occurrence of failure, limitation of layout in the electronic device, and the like do not occur. Additionally, since the region B of the insulation layer is prevented from being exposed to the etching gas, an interface between the active layer and the insulation layer is kept in a state same as when the organic semiconductor material layer is formed on the insulation layer, and performance degradation of the electronic device and the like can be prevented from occurrence.

Except for the above points, a composition and a structure of the electronic device of the fifth embodiment and a manufacturing method of the electronic device of the fifth embodiment may be similar to the compositions and structures of the electronic devices described in the first to fourth embodiments and the manufacturing methods of the electronic devices of the first to fourth embodiments. Therefore, a detailed description will be omitted.

### SIXTH EMBODIMENT

The sixth embodiment is a modification of first to fifth embodiments. In the sixth embodiment, a surface layer of a region A (21A) of the insulation layer 21 having a chemical composition different from a chemical composition of the region B (21B) of the insulation layer 21 is removed after patterning the active layer 12. Thus, removing the surface layer of the region A (21A) of the insulation layer 21 prevents a problem from occurring on the region A (21A) of the insulation layer 21 at the time of, for example, forming an electrode and the like.

Specifically, after patterning the active layer 12 in [Step-130] of the first embodiment, [Step-220] of the second embodiment, [Step-310] of the third embodiment, and [Step-420] of the fourth embodiment, the oxide film 22 is removed by wet etching or dry etching, and then the resist layer 15 is removed.

### SEVENTH EMBODIMENT

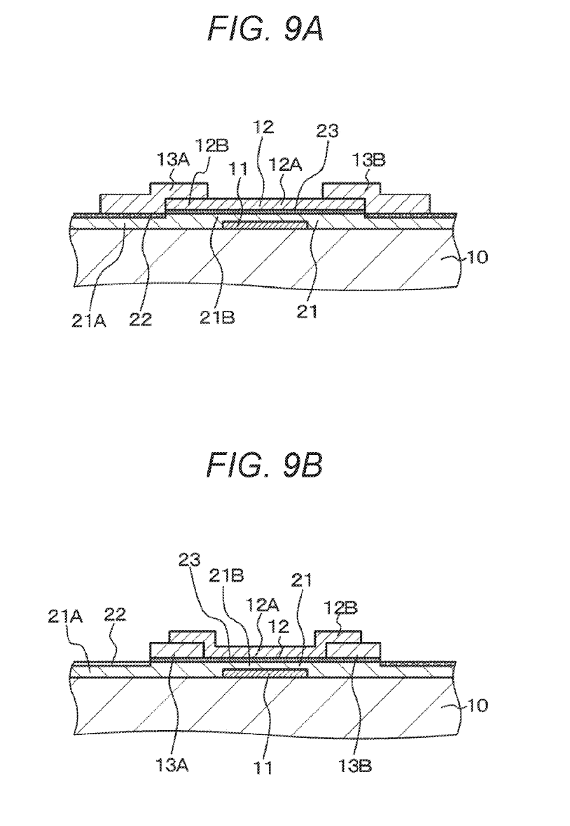

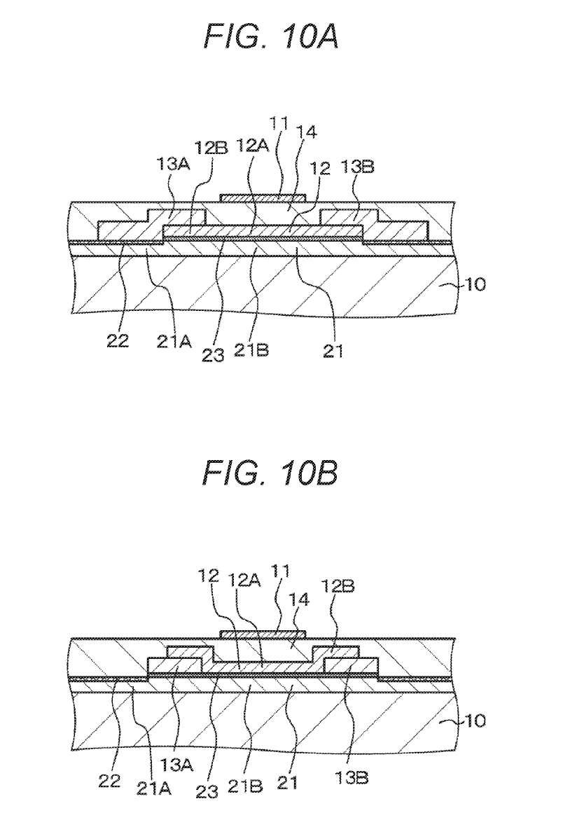

The seventh embodiment is a modification of the first to sixth embodiments. In the seventh embodiment, a second insulation layer 23 is formed between the active layer 12 and the region B (21B) of the insulation layer 21. Thus, the interface with the active layer can be set to a more desirable state by forming the second insulation layer 23 and making a two-layer structure of the second insulation layer 23 (upper layer) and the insulation layer 21 (lower layer). Here, specifically, the second insulation layer formed of an organic insulation film (such as poly-alpha-methylstyrene and TOPAS) may be formed on the insulation layer 21 after forming the insulation layer 21. A portion of the second insulation layer 23 on the region A (21A) of the insulation layer 21 is etched and removed at the time of patterning the active layer 12. For example, partial schematic cross-sectional view of the electronic device at the time of applying the seventh embodiment to the various kinds of electronic devices described in the first to fourth embodiments are illustrated in FIGS. 9A, 9B, 10A, and 10B.

### EIGHTH EMBODIMENT

An eighth embodiment relates to a sensor of the present disclosure. The sensor of the eighth embodiment is formed of an electronic device of a bottom gate/top contact type or a bottom gate/bottom contact type among electronic devices described in first to second embodiment and fifth to seventh embodiments. For example, a light emitting element is formed of the sensor of the eighth embodiment. In other words, the light emitting element (an organic light emitting element, an organic light emitting transistor), in which an active layer 12 emits light by applying voltage to a control electrode 11, a first electrode 13A, and second electrode 13B, is formed. Then, current flowing in the active layer 12 from the first electrode 13A to the second electrode 13B is controlled by the voltage applied to the control electrode 11. When bias to the first electrode 13A and the second electrode 13B is increased after positive holes are sufficiently accumulated, electron injection starts, and light is emitted by recombination with the positive holes.

Alternatively, as the sensor of the eighth embodiment, an optical sensor may be formed by using dyes having absorbing properties to light (including not only visible light but also ultraviolet light and infrared light) as an organic semiconductor molecule. Also, a photoelectric conversion element (specifically, solar cell and image sensor) in which current flows between the first electrode 13A and the second electrode 13B by irradiating the active layer 12 with light (including not only visible light but also ultraviolet light and infrared light) may be formed. Meanwhile, flowing current can be modulated by voltage application to the control electrode 11.

Also, an example may be a chemical substance sensor that measures an amount (concentration) of a chemical substance adsorbed on the active layer 12 by applying current between the first electrode 13A and the second electrode 13B or applying appropriate voltage between the first electrode 13A and the second electrode 13B by utilizing a fact that the electric resistance value between the first electrode 13A and the second electrode 13B is changed when the chemical substance to be detected is adsorbed onto the active layer 12, and then measuring an electric resistance value of the active layer 12.

While the description has been provided on the basis of the preferable embodiments of the present disclosure, the present disclosure is not limited to these embodiments. The electronic devices, image display devices, sensor, compositions, structures, forming conditions, manufacturing conditions of the manufacturing methods of the electronic devices described in the working examples are examples, and can be suitably changed. In the case of applying and using the electronic device obtained by the present disclosure, for example, in an image display device and various kinds of electronic apparatuses, the electronic device of the present disclosure may be used as a monolithic integrated circuit in which multiple electronic devices have been integrated in a base substrate, a support body, and a support member, or as a discrete component by cutting and individualizing respective electronic devices.

In the electronic devices described in the first to second embodiments, an insulation film may also be formed between the base substrate, control electrode, and insulation layer.

In the manufacturing method of the electronic device in the first embodiment, as the case may be, the resist layer may be removed after forming the resist layer adapted to cover the region B (21B) of the insulation layer 21 and forming the region A (21A) of the insulation layer 21 and the oxide film 22 by etching the insulation layer 21 by using oxygen gas between [Step-110] and [Step-120], and then patterning the active layer 12 in [Step-120] may be performed. Similarly, in the manufacturing method of the electronic device in the second embodiment, as the case may be, the resist layer may be removed after forming the resist layer adapted to cover the region B (21B) of the insulation layer 21, and forming the region A (21A) of the insulation layer 21 and the oxide film 22 by etching the insulation layer 21 by using oxygen gas between [Step-210] and [Step-220], and patterning the active layer 12 in [Step-220] may be performed. Furthermore, in the manufacturing method of the electronic device in the third embodiment, as the case may be, the resist layer may be removed after forming the resist layer adapted to cover the region B (21B) of the insulation layer 21 and forming the region A (21A) of the insulation layer 21 and the oxide film 22 by etching the insulation layer 21 by using oxygen gas between [Step-300] and [Step-310], and then patterning the active layer 12 in [Step-310] may be performed. Furthermore, in the manufacturing method of the electronic device in the fourth embodiment, as the case may be, the resist layer may be removed after forming the resist layer adapted cover the region B (21B) of the insulation layer 21 and forming the region A (21A) of the insulation layer 21 and the oxide film 22 by etching the insulation layer 21 by using oxygen gas between [Step-410] and [Step-420], and then patterning the active layer 12 in [Step-420] may be performed. In the fifth embodiment also, processes similar to those described above may be adopted as well.

Note that the present disclosure may also take the following configurations.

[A01] <Electronic Device: First Aspect . . . Bottom Gate/Top Contact Type>

An electronic device including:

a control electrode formed on a base substrate;

an insulation layer adapted to cover the control electrode and formed of an organic insulation material;

an active layer formed on the insulation layer, formed of an organic semiconductor material, and subjected to patterning; and

a first electrode and a second electrode formed on the active layer,

wherein a chemical composition of a surface of a region A that is a region of the insulation layer not formed with the active layer differs from a chemical composition of a region B that is a region of the insulation layer located under the active layer.

[A02] <Electronic Device: Second Aspect . . . Bottom Gate/Bottom Contact Type>

An electronic device including:

a control electrode formed on a base substrate;

an insulation layer adapted to cover the control electrode and formed of an organic insulation material;

a first electrode and a second electrode formed on the insulation layer; and

an active layer formed on at least a portion of the insulation layer located between the first electrode and the second electrode, formed of an organic semiconductor material, and subjected to patterning,

wherein a chemical composition of a surface of a region A that is a region of the insulation layer not formed with the first electrode, the second electrode, and the active layer differs from a chemical composition of a region B that is a region of the insulation layer located under the first electrode, the second electrode, and the active layer.

[A03] The electronic device according to [A01] or [A02], wherein an insulation film is formed between the base substrate, control gate, and insulation layer.

[A04] <Electronic Device: Third Aspect . . . Top Gate/Top Contact Type>

An electronic device, including:

an insulation layer formed on a base substrate and formed of an organic insulation material;

an active layer formed on the insulation layer, formed of an organic semiconductor material, and subjected to patterning;

a first electrode and a second electrode formed on a portion of the active layer;

an interlayer insulation layer adapted to cover the first electrode, the second electrode, and active layer; and

a control electrode formed on the interlayer insulation layer and facing the active layer,

wherein a chemical composition of a surface of a region A that is a region of the insulation layer not formed with the active layer differs from a chemical composition of a region B that is a region of the insulation layer located under the active layer.

[A05] <Electronic Device: Fourth Aspect . . . Top Gate/Bottom Contact Type>

An electronic device including:

an insulation layer formed on a base substrate and formed of an organic insulation material;

a first electrode and a second electrode formed on the insulation layer;

an active layer formed on a portion of the insulation layer located between the first electrode and the second electrode, formed of an organic semiconductor material, and subjected to patterning;

an interlayer insulation layer adapted to cover the first electrode, the second electrode, and active layer; and

a control electrode formed on the interlayer insulation layer and facing the active layer,

wherein a chemical composition of a surface of a region A that is a region of the insulation layer not formed with the first electrode, the second electrode, and the active layer differs from a chemical composition of a region B that is a region of the insulation layer located under the first electrode, the second electrode, and the active layer.

[A06] The electronic device according to [A04] or [A05], wherein an insulation film is formed between the base substrate and the insulation layer.

[A07] The electronic device according to any one of [A01] to [A05], wherein a second insulation layer is formed between the active layer and the region B of the insulation layer.

[A08] The electronic device according to any one of [A01] to [A07], wherein a level difference between the surface of the region A of the insulation layer and a surface of the region B of the insulation layer is 2×10⁻⁷ m or less.

[A09] The electronic device according to [A08], wherein the level difference between the surface of the region A of the insulation layer and the surface of the region B of the insulation layer is 5×10⁻⁸ m or less.

[A10] The electronic device according to any one of [A01] to [A09], wherein an oxygen content concentration in the region A of the insulation layer is higher than an oxygen content concentration in the region B of the insulation layer.

[A11] The electronic device according to any one of [A01] to [A10], wherein a metallic atom is included in constituent atoms of the insulation layer.

[A12] The electronic device according to [A11], wherein metal oxide obtained by binding oxygen with the metallic atom constituting the insulation layer is included in a surface of the region A of the insulation layer.

[A13] The electronic device according to any one of [A01] to [A12], wherein the organic insulation material has a composition formed of: silicone resin including copolymer crosslinked polymer and graft copolymer crosslinked polymer; silicon germanium polymer including polysilane and polygermane; silsesquioxane; stanniferous polymer; cobaltiferous polymer; at least one kind of insulation material selected from a group formed of polymer materials including a metallic atom in a main chain or a side chain of a, b-unsaturated carbene, or has a composition formed of mixture of any one of these materials with at least one kind of resin selected from a group formed of a polyvinyl-phenol resin, a polymide resin, a novolac resin, a cinnamate resin, an acrylic resin, an epoxy resin, a styrene resin, and a polyparaxylylene resin.

[A14] The electronic device according to any one of [A01] to [A10], wherein the organic insulation material is formed of a material in which metal oxide nanoparticles are dispersed in the polymer material

[B01 <Manufacturing Method of Electronic Device: First Aspect . . . Bottom Gate/Top Contact Type>

A manufacturing method of an electronic device, including respective steps of:

forming a control electrode on a base substrate;

forming an insulation layer formed of an organic insulation material and adapted to cover the control electrode;

subsequently forming, on the insulation layer, an active layer formed of an organic semiconductor material and subjected to patterning; and then

forming a first electrode and a second electrode on the active layer,

wherein, at the time of patterning the active layer, a chemical composition of a surface of a region A that is a region of the insulation layer not formed with the active layer is made to differ from a chemical composition of a region B that is a region of the insulation layer located under the active layer.

[B02] <Manufacturing Method of Electronic Device: Second Aspect . . . Bottom Gate/Bottom Contact Type>

A manufacturing method of an electronic device, including respective steps of:

forming a control electrode on a base substrate;

forming an insulation layer formed of an organic insulation material and adapted to cover the control electrode; and

subsequently forming a first electrode and a second electrode on the insulation layer; and then

forming, at least on a portion of the insulation layer located between the first electrode and the second electrode, an active layer formed of an organic semiconductor material and subjected to patterning,

wherein, at the time of patterning the active layer, a chemical composition of a surface of a region A that is a region of the insulation layer not formed with the first electrode, the second electrode, and the active layer is made to differ from a chemical composition of a region B that is a region of the insulation layer located under the first electrode, the second electrode, and the active layer.

[B03] <Manufacturing Method of Electronic Device: Third Aspect . . . Top Gate/Top Contact Type>

A manufacturing method of an electronic device, including respective steps of:

forming an insulation layer formed of an organic insulation material on a base substrate;

subsequently forming, on the insulation layer, an active layer formed of an organic semiconductor material and subject to patterning;

forming a first electrode and a second electrode on a part of the active layer;

subsequently forming an interlayer insulation layer adapted to cover the first electrode, the second electrode, and the active layer; and then

forming a control electrode facing the active layer on the interlayer insulation layer,

wherein, at the time of patterning the active layer, a chemical composition of a surface of a region A that is a region of the insulation layer not formed with the active layer is made to differ from a chemical composition of a region B that is a region of the insulation layer located under the active layer.

[B04] <Manufacturing Method of Electronic Device: Fourth Aspect . . . Top Gate/Bottom Contact Type>

A manufacturing method of an electronic device, including respective steps of:

forming an insulation layer formed of an organic insulation material on a base substrate;

subsequently forming a first electrode and a second electrode on the insulation layer;

forming, on a portion of the insulation layer located between the first electrode and the second electrode, an active layer formed of an organic semiconductor material and subjected to patterning;

subsequently forming an interlayer insulation layer adapted to cover the first electrode, the second electrode, and the active layer; and then

forming, on a control electrode facing the active layer on the interlayer insulation layer,

wherein, at the time of patterning the active layer, a chemical composition of a surface of a region A that is a region of the insulation layer not formed with the first electrode, the second electrode, and the active layer is made to differ from a chemical composition of a region B that is a region of the insulation layer located under the first electrode, the second electrode, and the active layer.

[B05] The manufacturing method of an electronic device according to any one of [B01] to [B04], wherein the chemical composition of the surface of the region A of the insulation layer is made to differ from the chemical composition of the region B of the insulation layer by reacting etching gas with an organic insulation material constituting the region A of the insulation layer at the time of patterning the active layer on the basis of a dry etching method.

[B06] The manufacturing method of an electronic device according to any one of [B01] to [B04], wherein the chemical composition of the surface layer of the region A of the insulation layer is made to differ from the chemical composition of the region B of the insulation layer by removing the region A of the insulation layer at the time of patterning the active layer on the basis of the dry etching method.

[B07] The manufacturing method of an electronic device according to any one of [B01] to [B04], wherein a surface layer of the region A of the insulation layer is removed after patterning the active layer.

### REFERENCE SIGNS LIST

10 Base substrate
11 Control electrode (gate electrode)
12 Active layer
12A Channel Forming Region
12B Channel Forming Region Extending Portion
12C Organic Semiconductor Material Layer
13, 13A, 13B First electrode and second electrode (source/drain electrodes)
14 Interlayer Insulation Layer
15 Resist layer
21 Insulation layer
21A Region A to be region of insulation layer not formed with active layer
21B Region B to be region of insulation layer located under active layer
22 Oxide Film
23 Second insulation layer

1. An electronic device comprising:
a control electrode formed on a base substrate;
an insulation layer configured to cover the control electrode and formed of an organic insulation material;
an active layer formed on the insulation layer, formed of an organic semiconductor material, and subjected to patterning; and
a first electrode and a second electrode formed on the active layer,
wherein a chemical composition of a surface of a region A that is a region of the insulation layer not formed with the active layer differs from a chemical composition of a region B that is a region of the insulation layer located under the active layer.

2. An electronic device comprising:
a control electrode formed on a base substrate;
an insulation layer configured to cover the control electrode and formed of an organic insulation material;
a first electrode and a second electrode formed on the insulation layer; and
an active layer formed on at least a portion of the insulation layer located between the first electrode and the second electrode, formed of an organic semiconductor material, and subjected to patterning,
wherein a chemical composition of a surface of a region A that is a region of the insulation layer not formed with the first electrode, the second electrode, and the active layer differs from a chemical composition of a region B that is a region of the insulation layer located under the first electrode, the second electrode, and the active layer.

3. An electronic device, comprising:
an insulation layer formed on a base substrate and formed of an organic insulation material;
an active layer formed on the insulation layer, formed of an organic semiconductor material, and subjected to patterning;
a first electrode and a second electrode formed on a portion of the active layer;
an interlayer insulation layer configured to cover the first electrode, the second electrode, and active layer; and
a control electrode formed on the interlayer insulation layer and facing the active layer,
wherein a chemical composition of a surface of a region A that is a region of the insulation layer not formed with the active layer differs from a chemical composition of a region B that is a region of the insulation layer located under the active layer.

4. An electronic device comprising:
an insulation layer formed on a base substrate and formed of an organic insulation material;
a first electrode and a second electrode formed on the insulation layer;
an active layer formed on a portion of the insulation layer located between the first electrode and the second electrode, formed of an organic semiconductor material, and subjected to patterning;
an interlayer insulation layer configured to cover the first electrode, the second electrode, and the active layer; and
a control electrode formed on the interlayer insulation layer and facing the active layer,
wherein a chemical composition of a surface of a region A that is a region of the insulation layer not formed with the first electrode, the second electrode, and the active layer differs from a chemical composition of a region B that is a region of the insulation layer located under the first electrode, the second electrode, and the active layer.

5. The electronic device according to claim 1, wherein a second insulation layer is formed between the active layer and the region B of the insulation layer.

6. The electronic device according to claim 1, wherein a level difference between the surface of the region A of the insulation layer and a surface of the region B of the insulation layer is 2×10⁻⁷ m or less.

7. The electronic device according to claim 6, wherein the level difference between the surface of the region A of the insulation layer and the surface of the region B of the insulation layer is 5×10⁻⁸ m or less.

8. The electronic device according to claim 1, wherein an oxygen content concentration in the region A of the insulation layer is higher than an oxygen content concentration in the region B of the insulation layer.

9. The electronic device according to claim 1, wherein a metallic atom is included in constituent atoms of the insulation layer.

10. The electronic device according to claim 9, wherein metal oxide obtained by binding oxygen with the metallic atom constituting the insulation layer is included in a surface of the region A of the insulation layer.

11. The electronic device according to claim 1, wherein the organic insulation material has a composition formed of: silicone resin including copolymer crosslinked polymer and graft copolymer crosslinked polymer; silicon germanium polymer including polysilane and polygermane; silsesquioxane; stanniferous polymer; cobaltiferous polymer; at least one kind of insulation material selected from a group formed of polymer materials including a metallic atom in a main chain or a side chain of a, b-unsaturated carbene, or has a composition formed of mixture of any one of these materials with at least one kind of resin selected from a group formed of a polyvinyl-phenol resin, a polymide resin, a novolac resin, a cinnamate resin, an acrylic resin, an epoxy resin, a styrene resin, and a polyparaxylylene resin.

12. The electronic device according to claim 1, wherein the organic insulation material is formed of a material in which metal oxide nanoparticles are dispersed in the polymer material

13. A manufacturing method of an electronic device, comprising respective steps of:
forming a control electrode on a base substrate;
subsequently forming an insulation layer formed of an organic insulation material and configured to cover the control electrode;
subsequently forming, on the insulation layer, an active layer formed of an organic semiconductor material and subjected to patterning; and then
forming a first electrode and a second electrode on the active layer,
wherein, at the time of patterning the active layer, a chemical composition of a surface of a region A that is a region of the insulation layer not formed with the active layer is made to differ from a chemical composition of a region B that is a region of the insulation layer located under the active layer.

14. A manufacturing method of an electronic device, comprising respective steps of:
forming a control electrode on a base substrate;
subsequently forming an insulation layer formed of an organic insulation material and configured to cover the control electrode; and
subsequently forming a first electrode and a second electrode on the insulation layer; and then
forming, at least on a portion of the insulation layer located between the first electrode and the second electrode, an active layer formed of an organic semiconductor material and subjected to patterning,
wherein, at the time of patterning the active layer, a chemical composition of a surface of a region A that is a region of the insulation layer not formed with the first electrode, the second electrode, and the active layer is made to differ from a chemical composition of a region B that is a region of the insulation layer located under the first electrode, the second electrode, and the active layer.

15. A manufacturing method of an electronic device, comprising respective steps of:
forming an insulation layer formed of an organic insulation material on a base substrate;
subsequently forming, on the insulation layer, an active layer formed of an organic semiconductor material and subject to patterning;
forming a first electrode and a second electrode on a part of the active layer;
subsequently forming an interlayer insulation layer configured to cover the first electrode, the second electrode, and the active layer; and then
forming a control electrode facing the active layer on the interlayer insulation layer,
wherein, at the time of patterning the active layer, a chemical composition of a surface of a region A that is a region of the insulation layer not formed with the active layer is made to differ from a chemical composition of a region B that is a region of the insulation layer located under the active layer.

16. A manufacturing method of an electronic device, comprising respective steps of:
forming an insulation layer formed of an organic insulation material on a base substrate;
subsequently forming a first electrode and a second electrode on the insulation layer;
forming, on a portion of the insulation layer located between the first electrode and the second electrode, an active layer formed of an organic semiconductor material and subjected to patterning;
subsequently forming an interlayer insulation layer configured to cover the first electrode, the second electrode, and the active layer; and then
forming a control electrode facing the active layer on the interlayer insulation layer,
wherein, at the time of patterning the active layer, a chemical composition of a surface of a region A that is a region of the insulation layer not formed with the first electrode, the second electrode, and the active layer is made to differ from a chemical composition of a region B that is a region of the insulation layer located under the first electrode, the second electrode, and the active layer.

17. The manufacturing method of an electronic device according to claim 13, wherein the chemical composition of the surface of the region A of the insulation layer is made to differ from the chemical composition of the region B of the insulation layer by reacting etching gas with an organic insulation material constituting the region A of the insulation layer at the time of patterning the active layer on the basis of a dry etching method.

18. The manufacturing method of an electronic device according to claim 13, wherein the chemical composition of the surface of the region A of the insulation layer is made to differ from the chemical composition of the region B of the insulation layer by removing a surface layer of the region A of the insulation layer at the time of patterning the active layer on the basis of the dry etching method.

19. The manufacturing method of an electronic device according to claim 13, wherein a surface layer of the region A of the insulation layer is removed after patterning the active layer.
